(19) United States
(12) Patent Application Publication
(10) Pub. No.: US 2026/0020237 A1
(43) Pub. Date: Jan. 15, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventors: Hyun Seung YOO, Gyeonggi-do (KR); Eun Mee KWON, Gyeonggi-do (KR); Eun Seok CHOI, Gyeonggi-do (KR)

(21) Appl. No.: 19/026,384

(22) Filed: Jan. 17, 2025

(30) Foreign Application Priority Data
Jul. 12, 2024 (KR) 10-2024-0092239
Dec. 10, 2024 (KR) 10-2024-0182873

(51) Int. Cl. H10B 43/27; H01L 23/00; H01L 25/18; H10B 43/35; H10B 80/00; H10D 30/01; H10D 30/69; H10D 62/834; H10D 64/01; H10D 64/68; H10D 80/30

(52) U.S. Cl. CPC H10B 43/27; H01L 24/08; H01L 25/18; H10B 43/35; H10B 80/00; H10D 30/693; H10D 62/834; H10D 64/683; H10D 64/691; H10D 64/693; H10D 80/30; H01L 2224/08145; H01L 2225/06544; H01L 2924/1431; H01L 2924/1438; H10D 30/0413; H10D 64/037

(57) ABSTRACT

A semiconductor device may include a gate structure including alternately stacked insulating layers and conductive layers, a slit structure extending through the gate structure, a channel layer extending through the gate structure, a first data storage layer surrounding the channel layer, second data storage patterns respectively positioned between the conductive layers and the first data storage layer, first blocking patterns respectively positioned between the conductive layers and the second data storage patterns, and buffer patterns positioned between the insulating layers and the first data storage layer.

### CROSS-REFERENCE TO RELATED APPLICATION

This application claims priority under 35 U.S.C. § 119 to Korean Patent Application No. 10-2024-0092239 filed on Jul. 12, 2024, and Korean Patent Application No. 10-2024-0182873 filed on Dec. 10, 2024, which are incorporated herein by reference in its entirety.

### BACKGROUND

### 1. Technical Field

Embodiments of the present disclosure relate generally to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvements in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed to improve operation reliability of the semiconductor device.

### SUMMARY

According to an embodiment of the present disclosure, a semiconductor device may include a gate structure including alternately stacked insulating layers and conductive layers, a slit structure extending through the gate structure, a channel layer extending through the gate structure, a first data storage layer surrounding the channel layer, second data storage patterns respectively positioned between the conductive layers and the first data storage layer, first blocking patterns respectively positioned between the conductive layers and the second data storage patterns, and buffer patterns positioned between the insulating layers and the first data storage layer.

According to an embodiment of the present disclosure, a method of manufacturing a semiconductor device may include forming a stack of alternating first and second material layers, forming a channel hole extending through the stack, sequentially forming a first data storage layer, a tunneling layer, and a channel layer in the channel hole, forming a slit extending through the stack, forming openings exposing the first data storage layer by removing the second material layers through the slit, selectively forming second data storage patterns on the first data storage layer through the openings, and forming conductive layers in the openings.

These and other features and advantages of the present invention will become better understood by the skilled person from the following detailed description of embodiments of the present invention in conjunction with the following drawings.

### BRIEF DESCRIPTION OF THE DRAWINGS

FIGS. 1A and 1B are diagrams illustrating a semiconductor device according to an embodiment of the present disclosure.

FIG. 2 is a diagram illustrating a semiconductor device according to an embodiment of the present disclosure.

FIGS. 3A and 3B are diagrams illustrating an effect of a semiconductor device according to an embodiment of the present disclosure.

FIGS. 4A and 4B are diagrams illustrating an effect of a semiconductor device according to an embodiment of the present disclosure.

FIGS. 5A to 5F are diagrams illustrating a method of manufacturing a semiconductor device according to an embodiment of the present disclosure.

FIG. 6 is a drawing illustrating a semiconductor device according to an embodiment of the present disclosure.

FIG. 7 is a configuration diagram of a semiconductor device according to an embodiment of the present disclosure.

FIG. 8 is a configuration diagram of a semiconductor device according to an embodiment of the present disclosure.

### DETAILED DESCRIPTION

An embodiment of the present disclosure provides a semiconductor device and a method of manufacturing the semiconductor device having a stable structure and improved characteristics.

According to the present technology, a semiconductor device having a stable structure and improved reliability may be provided.

Hereinafter, embodiments according to the technical concept of the present disclosure are described with reference to the accompanying drawings.

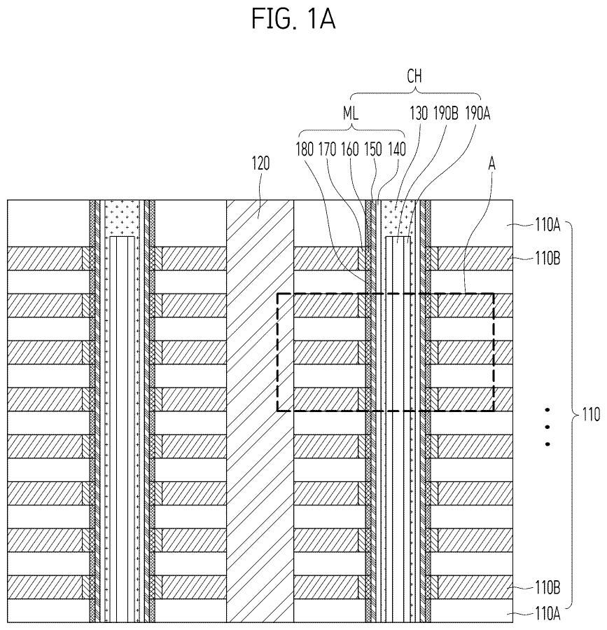

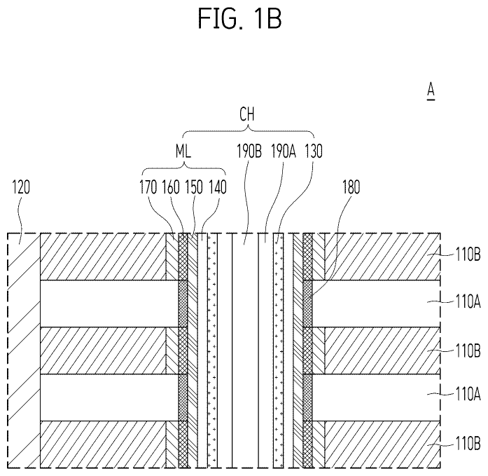

FIGS. 1A and 1B are diagrams illustrating a semiconductor device according to an embodiment of the present disclosure. FIG. 1A is a cross-sectional view, and FIG. 1B is an enlarged view of section A of FIG. 1A.

Referring to FIGS. 1A and 1B, the semiconductor device may include a gate structure 110, a slit structure 120, buffer patterns 180, and a channel structure CH.

The gate structure 110 may include insulating layers 110A and conductive layers 110B that are alternately stacked. The conductive layers 110B may be a gate line such as a source select line, a word line, or a drain select line. A source select transistor, a memory cell, or a drain select transistor may be positioned in an area where the channel structures CH and the conductive layers 110B intersect. For example, at least one source select transistor, a plurality of memory cells, and at least one drain select transistor stacked along the channel structure CH may configure one memory string. The insulating layers 110A may include an insulating material such as oxide. The conductive layers 110B may include a conductive material such as tungsten, molybdenum, or polysilicon.

The slit structure 120 may extend through the gate structure 110. The slit structure 120 may pass through the gate structure 110. The slit structure 120 may be used as a path for forming the gate structure 110, the channel structures CH, or the like in a process of manufacturing the semiconductor device. The slit structure 120 may include an insulating material, a conductive material, or a semiconductor material.

The channel structure CH may extend through the gate structure 110. The channel structure CH may include at least one of a channel layer 130, a memory layer ML, a first insulating core 190A, and a second insulating core 190B.

The channel layer 130 may extend through the gate structure 110. For example, the channel layer 130 may pass through the gate structure 110. The channel layer 130 may include a semiconductor material. For example, the channel layer 130 may include polysilicon, germanium, or the like.

A grain boundary may exist in the channel layer 130. When there are many grain boundaries in the channel layer 130, mobility of charges in the channel layer 130 may be reduced. According to an embodiment of the present disclosure, the channel layer 130 may include at least one of hydrogen and deuterium. In a process of manufacturing the semiconductor device, at least one of hydrogen and deuterium may be injected into the channel layer 130, and hydrogen or deuterium may be trapped in a trap site of the grain boundary existing in the channel layer 130. In this case, layer quality of the channel layer 130 may be improved and the mobility of the charges may be increased.

The memory layer ML may include a tunneling layer 140, a first data storage layer 150, second data storage patterns 160, and blocking patterns 170.

The tunneling layer 140 may surround the channel layer 130. When a bias is applied to the conductive layers 110B, the tunneling layer 140 may be used as a path allowing charges in the channel layer 130 to tunnel to the first data storage layer 150 and/or the second data storage patterns 160. The tunneling layer 140 may include an insulating material such as oxide, e.g., SiO₂.

The first data storage layer 150 may surround the channel layer 130. The first data storage layer 150 may be positioned on the tunneling layer 140. Charges may be trapped in the first data storage layer 150, and data may be stored in a bit form. The first data storage layer 150 may be used as a seed layer for forming the second data storage patterns 160 in the process of manufacturing the semiconductor device. The first data storage layer 150 may include silicon nitride, such as, for example, Si₃N₄.

The second data storage patterns 160 may be positioned on the first data storage layer 150. For example, the second data storage patterns 160 may be positioned between the conductive layers 110B and the first data storage layer 150, respectively. The first data storage layer 150 may have a thickness thinner than a thickness of the second data storage patterns 160. Charges may be trapped in the second data storage patterns 160, and data may be stored in a bit form.

The second data storage patterns 160 may include a material substantially equal to a material of the first data storage layer 150. The second data storage patterns 160 may include a material different from the material of the first data storage layer 150. For example, the second data storage patterns 160 may include substantially the same material as the first data storage layer 150. For example, the second data storage patterns 160 may include silicon nitride. The second data storage patterns 160 may include Si₃N₄. In another embodiment, the second data storage patterns 160 may include a material different from the material of the first data storage layer 150. For example, the second data storage patterns 160 may include silicon carbonitride, e.g., SiCN.

According to the prior art, the data storage layer may be a single layer, may have a shape surrounding a sidewall of the channel layer, and data storage layers of stacked memory cells may be connected to each other. When a gap between conductive layers of the gate structure is reduced to improve an integration degree of the semiconductor device, charges may move between the stacked memory cells. Therefore, the reliability of the memory cell may decrease.

According to an embodiment of the present disclosure, the data storage layer included in the memory cells may be configured of a plurality of layers. For example, each of the memory cells may include the first data storage layer 150 and the second data storage pattern 160.

Here, the first data storage layer 150 may have a thickness thinner than a thickness of a data storage layer of the prior art. In this case, the first data storage layer 150 may trap a lesser amount (or number) of charges compared to the data storage layer of the prior art, and may reduce spreading of the trapped charges to an adjacent area.

The second data storage patterns 160 may be positioned on the first data storage layer 150 and may be spaced apart from each other in a vertical direction. In this case, reduction of an amount (or number) of charges trapped by the first data storage layer 150 may be compensated, and because the second data storage patterns 160 are spaced apart from each other, the spread of the trapped charges to an adjacent area may be prevented or reduced.

According to an embodiment of the present disclosure, a thickness of the first data storage layer 150 having a form in which data storage layers of stacked memory cells are connected to each other may be formed to be relatively thin, and movement of a charge between the stacked memory cells may be reduced by forming the second data storage patterns 160 spaced apart from each other in a vertical direction. Therefore, reliability of the memory cell may be increased.

The blocking patterns 170 may be positioned on the second data storage patterns 160, respectively. For example, the blocking patterns 170 may be positioned between the conductive layers 110B and the second data storage patterns 160, respectively. The blocking patterns 170 may prevent charges from moving between the conductive layers 110B and the first data storage layer 150 and/or the second data storage patterns 160. The blocking patterns 170 may include silicon oxide. For example, the blocking patterns 170 may include SiO₂. Alternatively, the blocking patterns 170 may include a material of which a dielectric constant is great. For example, the blocking patterns 170 may include at least one of aluminum oxide, hafnium oxide, and zirconium oxide. The blocking patterns 170 may include at least one of Al₂O₃, HfO₂, and ZrO₂.

The buffer patterns 180 may be positioned on the first data storage layer 150. For example, the buffer patterns 180 may be positioned between the insulating layers 110A and the first data storage layer 150. The buffer patterns 180 may be a residue, which is not removed, of a buffer layer used as an etch stop layer in the manufacturing process of the semiconductor device. The buffer patterns 180 may include oxide.

The first insulating core 190A may extend through the gate structure 110. The first insulating core 190A may be positioned inside the channel layer 130. The first insulating core 190A may be used to increase mobility of charges in the channel layer 130 in the process of manufacturing the semiconductor device. The first insulating core 190A may include nitride. For example, the first insulating core 190A may include silicon nitride.

The second insulating core 190B may extend through the gate structure 110. The second insulating core 190B may be positioned in the first insulating core 190A. The second insulating core 190B may decrease warpage of a wafer. The second insulating core 190B may include a material having a stress different from a stress of the first insulating core 190A. The second insulating core 190B may include oxide. For example, the second insulating core 190B may include at least one of Al₂O₃, HfO₂, and ZrO₂.

When the first insulating core 190A includes nitride, a compressive stress may be applied to the wafer. When the second insulating core 190B includes oxide, a tensile stress may be applied to the wafer. Therefore, the compressive stress of the first insulating core 190A and the tensile stress of the second insulating core 190B may be offset, and the warpage of the wafer may decrease.

According to the structure described above, the semiconductor device may include the first data storage layer 150 and the second data storage patterns 160. The first data storage layer 150 and the second data storage patterns 160 may be used as one data storage layer. The first data storage layer 150 may have a relatively thin thickness, and the second data storage patterns 160 may be spaced apart from each other in the vertical direction. Therefore, spread of trapped charges to an adjacent area may be prevented or reduced, and reliability of the memory cell may be increased.

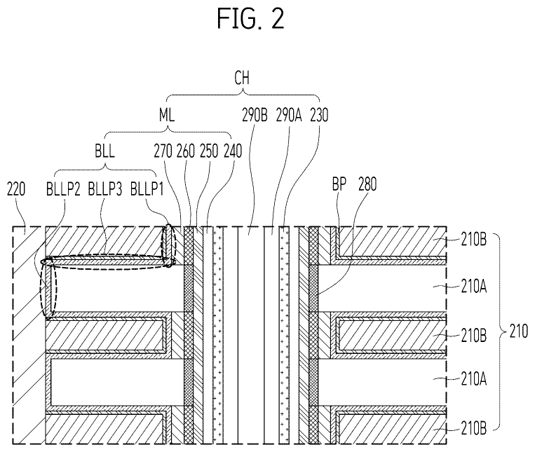

FIG. 2 is a diagram illustrating a semiconductor device according to an embodiment of the present disclosure. Hereinafter, content that overlaps the content described above is omitted.

Referring to FIG. 2, the semiconductor device may include a gate structure 210, a slit structure 220, buffer patterns 280, a channel structure CH, and barrier patterns BP.

The gate structure 210 may include insulating layers 210A and conductive layers 210B that are alternately stacked. The insulating layers 210A may include an insulating material such as oxide. The conductive layers 210B may include a conductive material such as tungsten, molybdenum, or polysilicon.

The slit structure 220 may extend through the gate structure 210. The slit structure 220 may be used as a path for forming the gate structure 210 or the channel structures CH in a process of manufacturing the semiconductor device. The slit structure 220 may include an insulating material, a conductive material, or a semiconductor material.

The channel structure CH may extend through the gate structure 210. The channel structure CH may include at least one of a channel layer 230, a memory layer ML, a first insulating core 290A, and a second insulating core 290B.

According to an embodiment of the present disclosure, the channel layer 230 may include at least one of hydrogen and deuterium. In the process of manufacturing the semiconductor device, at least one of hydrogen and deuterium may be injected into the channel layer 230, and hydrogen or deuterium may be trapped in a trap site of a grain boundary existing in the channel layer 230. In this case, layer quality of the channel layer 230 may be improved and mobility of charges may be increased.

The memory layer ML may include a tunneling layer 240, a first data storage layer 250, second data storage patterns 260, first blocking patterns 270, and a second blocking layer BLL.

The tunneling layer 240 may surround the channel layer 230. When a bias is applied to the conductive layers 210B, the tunneling layer 240 may be used as a path allowing charges in the channel layer 230 to tunnel to the first data storage layer 250 and/or the second data storage patterns 260. The tunneling layer 240 may include an insulating material such as oxide, and may include SiO₂.

The first data storage layer 250 may surround the channel layer 230. The charges may be trapped in the first data storage layer 250, and data may be stored in a bit form. The first data storage layer 250 may be used as a seed layer for forming the second data storage patterns 260 in the process of manufacturing the semiconductor device. The first data storage layer 250 may include silicon nitride, and may include Si₃N₄.

The second data storage patterns 260 may be positioned between the conductive layers 210B and the first data storage layer 250, respectively. The charges may be trapped in the second data storage patterns 260, and data may be stored in a bit form. The second data storage patterns 260 may include a material substantially equal to a material of the first data storage layer 250 or may include a material different from the material of the first data storage layer 250.

According to an embodiment of the present disclosure, a thickness of the first data storage layer 250 having a form in which data storage layers of stacked memory cells are connected to each other may be formed to be relatively thin, and movement of a charge between the stacked memory cells may be reduced by forming the data storage patterns 260 spaced apart from each other in a vertical direction. Therefore, reliability of the memory cell may be increased.

The first blocking patterns 270 may be positioned between the conductive layers 210B and the second data storage patterns 260, respectively. The first blocking patterns 270 may include silicon oxide. For example, the first blocking patterns 270 may include SiO₂.

The second blocking layer BLL may be positioned on the first blocking patterns 270. The second blocking layer BLL may include a first portion BLLP1, a second portion BLLP2, and a third portion BLLP3. Here, the first portion BLLP1 may be positioned between the conductive layers 210B and the first blocking pattern 270. The second portion BLLP2 may be positioned between the insulating layers 210A and the slit structure 220. The third portion BLLP3 may extend in a horizontal direction to connect the first portion BLLP1 and the second portion BLLP2. The third portions BLLP3 may be positioned between the insulating layers 210A and the conductive layers 210B.

The second blocking layer BLL may include a material of which a dielectric constant is greater than a dielectric constant of the first blocking patterns 270. For example, the second blocking layer BLL may include at least one of Al₂O₃, HfO₂, and ZrO₂.

During an erase operation of a memory cell, the charges in the conductive layers 210B may be back tunneled to the first data storage layer 250 and/or the second data storage layer 260. In this case, the charges trapped in the first data storage layer 250 and/or the second data storage layer 260 may not become un-trapped (or de-trapped) by the back tunneled charges. When an operation of the memory cell is repeated in such a state, endurance of the memory cell may be weakened.

According to an embodiment of the present disclosure, the first blocking patterns 270 and the second blocking layer BLL may prevent or reduce back tunneling of the charges of the conductive layers 210B to the first data storage layer 250 and/or the second data storage layer 260. For example, by forming the second blocking layer BLL in addition to the first blocking patterns 270, a thickness of the blocking layers 270 and BLL through which the back tunneled charges are required to be tunneled may be increased, thereby reducing a back tunneling phenomenon. In addition, when the second blocking layer BLL includes a material of which a dielectric constant is greater than a dielectric constant of the first blocking patterns 270, the energy required for the charges of the conductive layers 210B to tunnel through the second blocking layer BLL may be increased and the charges may be prevented from being back tunneled.

The barrier patterns BP may be positioned between the conductive layers 210B and the second blocking layer BLL. The barrier patterns BP may surround the conductive layers 210B. Here, the combination of the barrier pattern BP and the conductive layer 210B may be used as a gate line. The barrier patterns BP may include metal nitride. For example, the barrier patterns BP may include at least one of TaN (tantalum nitride) and WN (tungsten nitride).

The barrier patterns BP may increase the bonding strength of the conductive layers 210B in the process of forming the semiconductor device. In addition, the barrier patterns BP may prevent or reduce back tunneling of the charges of the conductive layers 210B to the first data storage layer 250 and/or the second data storage patterns 260.

The barrier patterns BP may increase the work function required for the charges of the conductive layers 210B to back tunnel. For example, compared to a case where the conductive layers 210B and the barrier patterns including TiN are bonded, when the conductive layers 210B and the barrier patterns BP including at least one of TaN and WN are bonded, the size of the work function required for the charges of the conductive layers 210B to back tunnel may be increased. In this case, the energy required for back tunneling may increase and the charges may be prevented from being back tunneled.

The first insulating core 290A may be positioned in the channel layer 230. The first insulating core 290A may be used to increase mobility of the charges in the channel layer 230 in the process of manufacturing the semiconductor device. The first insulating core 290A may include silicon nitride.

The second insulating core 290B may be positioned in the first insulating core 290A. The second insulating core 290B may include a material having a stress that is different from a stress of the first insulating core 290A. The second insulating core 290B may include an oxide and may include at least one of Al₂O₃, HfO₂, and ZrO₂. A compressive stress of the first insulating core 290A and a tensile stress of the second insulating core 290B may be offset, and a warpage of a wafer may decrease.

According to the structure described above, the semiconductor device may include the first blocking patterns 270 and the second blocking layer BLL. In this case, back tunneling of the charges of the conductive layers 210B to the first data storage layer 250 and/or the second data storage patterns 260 may be prevented or reduced.

In addition, the semiconductor device may include the barrier patterns BP. The barrier patterns BP may include at least one of TaN and WN, and may be bonded to the conductive layers 210B to increase the size of the work function required for the charges of the conductive layers 210B to back tunnel, thereby preventing the charges from being back tunneled.

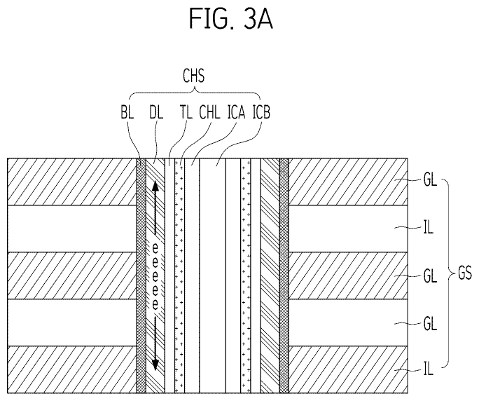

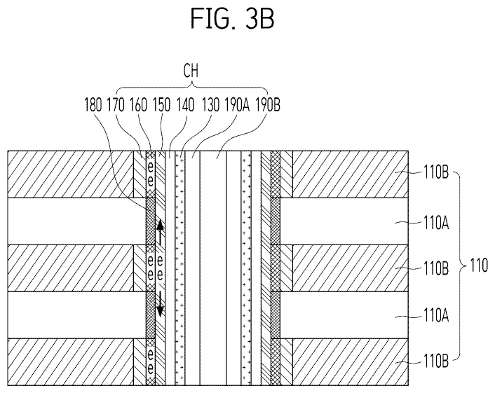

FIGS. 3A and 3B are diagrams illustrating an effect of a semiconductor device according to an embodiment of the present disclosure. Hereinafter, content that overlaps the content described above is omitted.

Referring to FIG. 3A, the semiconductor device may include a gate structure GS and a channel structure CHS. The gate structure GS may include insulating layers IL and conductive layers GL that are alternately stacked. The channel structure CHS may include a first insulating core ICA, a second insulating core ICB, a channel layer CHL, a tunneling layer TL, a data storage layer DL, and a blocking layer BL.

Referring to FIG. 3B, the semiconductor device may include a gate structure 110 and a channel structure CH. The gate structure 110 may include insulating layers 110A and conductive layers 110B that are alternately stacked. The channel structure CH may include a first insulating core 190A, a second insulating core 190B, a channel layer 130, a tunneling layer 140, a first data storage layer 150, second data storage patterns 160, and blocking patterns 170.

Comparing FIGS. 3A and 3B, a thickness of the first data storage layer 150 of FIG. 3B is relatively thinner than a thickness of the data storage layer DL of FIG. 3A. When the data storage layer DL is thick, an amount of trapped charges “e” is generally greater. In this case, when a gap between the conductive layers GL is reduced to improve an integration degree of the semiconductor device, the charges may be moved between stacked memory cells. Therefore, reliability of the memory cells may be reduced.

Because the first data storage layer 150 is thinner than the data storage layer DL, the amount of trapped charges in the first data storage layer 150 is less than the amount of trapped charges in the data storage layer DL. In this case, even though a gap between the conductive layers 110B may be reduced, the amount of charges transferred between the memory cells may be reduced.

The second data storage patterns 160 of FIG. 3B compensate for a reduction of the amount of the charges trapped by the first data storage layer 150. In addition, because the second data storage patterns 160 are spaced apart from each other in the vertical direction, trapped charges are prevented from spreading to an adjacent area. Therefore, reliability of the memory cells increases.

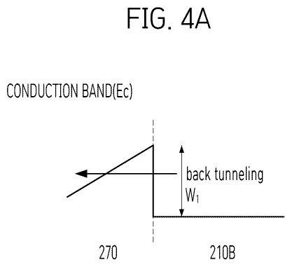

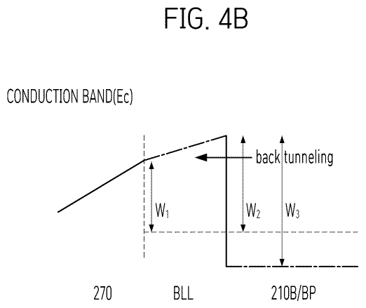

FIGS. 4A and 4B are diagrams illustrating an effect of a semiconductor device according to an embodiment of the present disclosure. Hereinafter, content that overlaps the content described above is omitted.

Referring to FIGS. 2 and 4A, for the charges in the conductive layers 210B to back tunnel through the first blocking patterns 270, energy equal to or greater than a first work function W₁ is required.

Referring to FIGS. 2 and 4B, the semiconductor device includes the first blocking patterns 270 and the second blocking layer BLL. Here, the second blocking layer BLL includes a material of which a dielectric constant is great. For example, the second blocking layer BLL includes at least one of Al₂O₃, HfO₂, and ZrO₂ of which a dielectric constant is greater than a dielectric constant of the first blocking patterns 270 (made of SiO₂). In this case, the energy required for the charges of the conductive layers 210B to tunnel through the second blocking layer BLL increases. Namely, energy equal to or greater than a second work function W₂ greater than the first work function W₁ is required.

In addition, the semiconductor device includes the barrier patterns BP surrounding the conductive layers 210B. The barrier pattern BP and the conductive layer 210B may be used as a gate line. The barrier patterns BP may include metal nitride and include at least one of TaN and WN. In this case, energy required for the charges of the conductive layers 210B to back tunnel increases. That is, energy equal to or greater than a third work function W₃ greater than the second work function W₂ is required.

Therefore, according to an embodiment of the present disclosure, by increasing a work function required for the charges of the conductive layers 210B to back tunnel by using the first blocking patterns 270, the second blocking layer BLL, and the barrier patterns BP, a back tunneling phenomenon may be prevented from occurring.

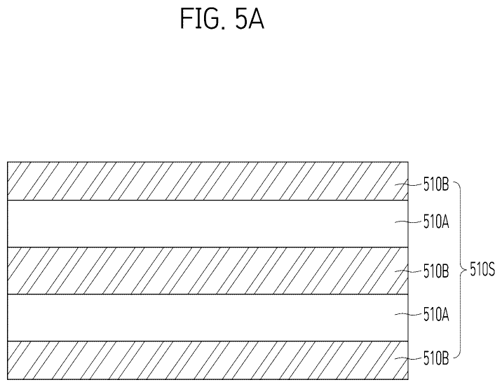

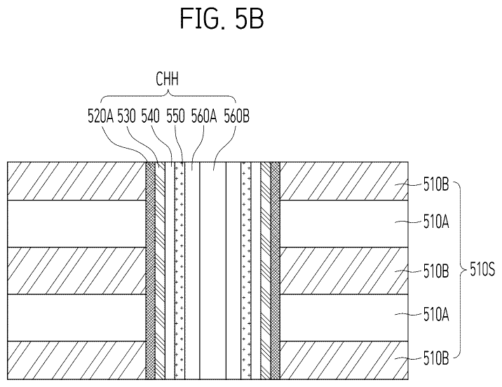

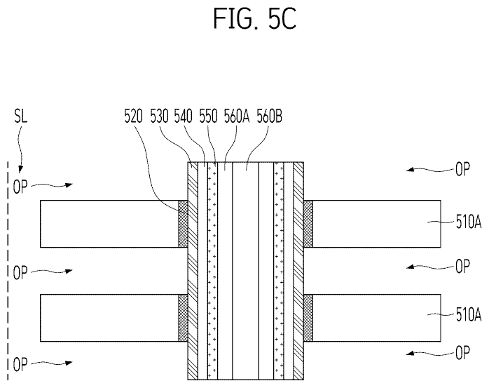

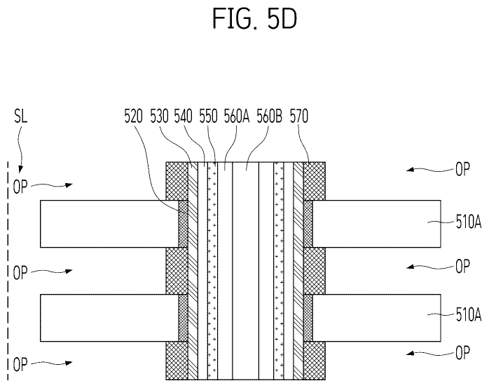

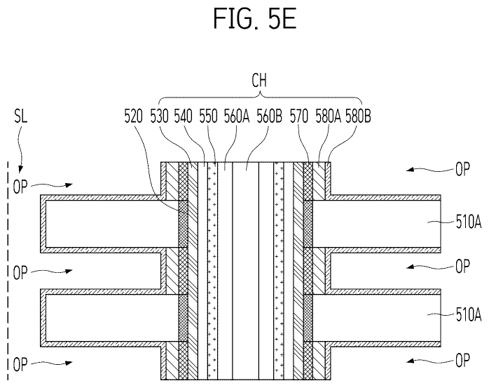

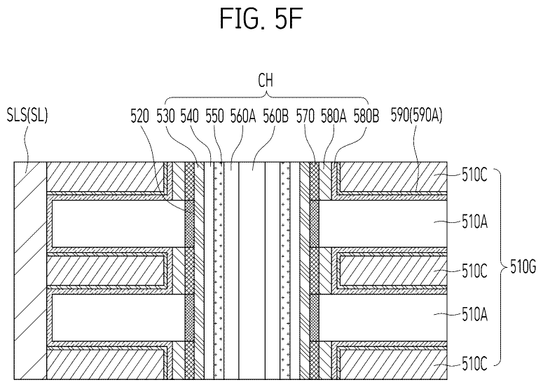

FIGS. 5A to 5F are diagrams illustrating a method of manufacturing a semiconductor device according to an embodiment of the present disclosure. Hereinafter, content that overlaps the content described above is omitted.

Referring to FIG. 5A, first material layers 510A and second material layers 510B may be alternately stacked to form a stack 510S. The first material layers 510A and/or the second material layers 510B may include a sacrificial material such as oxide or nitride. For example, the first material layers 510A may include oxide, and the second material layers 510B may include nitride.

Referring to FIG. 5B, a channel hole CHH extending through the stack 510S may be formed. Subsequently, a buffer layer 520A may be formed in the channel hole CHH. Here, the buffer layer 520A may include a material having a great etch selectivity with respect to the second material layers 510B. The buffer layer 520A may include an oxide.

Subsequently, a first data storage layer 530 may be formed in the channel hole CHH. Charges may be trapped in the first data storage layer 530, and data may be stored in a bit form. The first data storage layer 530 may be used as a seed layer for forming second data storage patterns in a subsequent process. The first data storage layer 530 may include silicon nitride, and may include Si₃N₄.

Subsequently, a tunneling layer 540 may be formed on the first data storage layer 530. When a bias is applied to the conductive layers, the tunneling layer 540 may provide a path through which charges in the channel layer 550 may tunnel to the first data storage layer 530 and/or the second data storage patterns 570. The tunneling layer 540 may include an insulating material such as oxide, and may include SiO₂.

Subsequently, a channel layer 550 may be formed on the tunneling layer 540. The channel layer 550 may include a semiconductor material. For example, the channel layer 550 may include polysilicon, germanium, or the like.

Subsequently, a first insulating core 560A may be formed on the channel layer 550. The first insulating core 560A may be used to increase mobility of the charges in the channel layer 550. The first insulating core 560A may include nitride. For example, the first insulating core 560A may include silicon nitride.

Subsequently, a second insulating core 560B may be formed on the first insulating core 560A. The second insulating core 560B may decrease warpage of the wafer. The second insulating core 560B may include a material having a stress different from a stress of the first insulating core 560A. The second insulating core 560B may include oxide. For example, the second insulating core 560B may include at least one of Al₂O₃, HfO₂, and ZrO₂.

When the first insulating core 560A includes nitride, a compressive stress may be applied to the wafer. When the second insulating core 560B includes oxide, a tensile stress may be applied to the wafer. Therefore, the compressive stress of the first insulating core 560A and the tensile stress of the second insulating core 560B may be offset, and the warpage of the wafer may decrease.

Referring to FIG. 5C, a slit SL extending through the stack 510S may be formed. Subsequently, the second material layers 510B may be removed through the slit SL to form openings OP exposing the buffer layer 520A. Here, the buffer layer 520A may be used as an etch stop layer. For example, the buffer layer 520A may prevent the first storage layer 530 from being exposed in a process of removing the second material layers 510B.

Subsequently, a portion of the buffer layer 520A may be removed through the openings OP to expose the first data storage layer 530. The buffer layer 520A remaining in an area corresponding to the first material layers 510A may be defined as buffer patterns 520.

In a process of removing a portion of the buffer layer 520A, a portion of the first material layers 510A may be etched. This is because the buffer layer 520A and the first material layers 510A include oxide which is substantially the same material. In this case, the openings OP may be expanded. Here, an area of the openings OP may be expanded so that a first thickness of conductive layers filling the openings OP in a subsequent process has a thickness similar to a thickness of the material layers 510A.

Subsequently, at least one of hydrogen and deuterium may be injected into the channel layer 550 through the openings OP. A grain boundary may exist in the channel layer 550, and when there are many grain boundaries, mobility of the charges in the channel layer 550 may be reduced. When at least one of hydrogen and deuterium is injected into the channel layer 550, hydrogen or deuterium may be trapped in a trap site of the grain boundary existing in the channel layer 550. In this case, layer quality of the channel layer 550 may be improved and mobility of the charges may be increased.

Referring to FIG. 5D, second data storage patterns 570 may be formed. For example, the second data storage patterns 570 may be selectively formed on the first data storage layer 530 through the openings OP. Here, the first data storage layer 530 may be used as a seed layer for forming the second data storage patterns 570.

The second data storage patterns 570 may include a material different from a material of the first data storage layer 530. For example, the second data storage patterns 570 may include silicon carbonitride (SiCN). The second data storage patterns 570 may include SiCN, and the first data storage layer 530 may include Si₃N₄.

Subsequently, nitrogen may be injected into the second data storage patterns 570. Through this, the material (SiCN) of the second data storage patterns 570 may be converted to have a property similar to the material (Si₃N₄) of the first data storage layer 530. For example, by converting the second data storage patterns 570 to be similar to the first data storage layer 530, a greater amount of charges may be trapped.

However, the embodiments of the present disclosure are not limited thereto, and the second data storage patterns 570 may include substantially the same material as the first data storage layer 530. For example, after forming the second data storage patterns 570 (SiCN), carbon (C) may be removed so that the second data storage patterns 570 may include Si₃N₄.

Referring to FIG. 5E, first blocking patterns 580A may be formed. For example, the first blocking patterns 580A may be formed by oxidizing the second data storage patterns 570. By forming the first blocking patterns 580A by oxidizing the second data storage patterns 570, a space for forming conductive layers in the openings OP may be secured in a subsequent process. The first blocking patterns 580A may include silicon oxide. For example, the first blocking patterns 580A may include SiO₂.

Subsequently, a second blocking layer 580B may be formed on the first blocking patterns 580A. Accordingly, a channel structure CH including the second blocking layer 580B, the first blocking patterns 580A, the second data storage patterns 570, the first data storage layer 530, the tunneling layer 540, the channel layer 550, the first insulating core 560A, and the second insulating core 560B may be formed. Here, the second blocking layer 580B may include a material having a dielectric constant which is greater than a dielectric constant of the first blocking patterns 580A. For example, the second blocking layer 580B may include oxide and may include at least one of Al₂O₃, HfO₂, and ZrO₂.

During an erase operation of a memory cell, charges of conductive layers may be back tunneled to the second data storage patterns 570 and/or the first data storage layer 530. In this case, the charges trapped in the second data storage patterns 570 and/or the first data storage layer 530 may not be de-trapped by the back tunneled charges. When an operation of the memory cell is repeated in such a state, endurance of the memory cell may be weakened.

According to an embodiment of the present disclosure, the first blocking patterns 580A and the second blocking layer 580B may be formed between the conductive layers and the second data storage patterns 570 and/or the first data storage layer 530, and the first blocking patterns 580A and the second blocking layer 580B may prevent or reduce back tunneling of the charges of the conductive layers to the second data storage patterns 570 and/or the first data storage layer 530. For example, by forming the second blocking layer 580B in addition to the first blocking patterns 580A, a thickness of the blocking layers 580A and 580B through which the back tunneled charges are required to be tunneled may be increased, thereby reducing a back tunneling phenomenon.

In addition, when the second blocking layer 580B includes a material having a dielectric constant which is greater than a dielectric constant of the first blocking patterns 580A, energy required for the charges of the conductive layers to tunnel through the second blocking layer 580B may be increased and the charges may be prevented from being back tunneled.

For reference, in this drawing, an embodiment in which the second blocking layer 580B is formed is described, but a process of forming the second blocking layer 580B may be omitted. In this case, the first blocking patterns 580A may include silicon oxide and may include SiO₂. Alternatively, the first blocking patterns 580A may include a material having a dielectric constant which is great and may include at least one of Al₂O₃, HfO₂, and ZrO₂.

Referring to FIG. 5F, a barrier layer 590A may be formed in the openings OP. For example, the barrier layer 590A may be formed along a profile of the second blocking layer 580B. The barrier layer 590A may include metal nitride and may include at least one of TaN and WN. Subsequently, conductive layers 510C may be formed in the openings OP. Through this, a gate structure 510G in which the first material layers 510A and the conductive layers 510C are alternately stacked may be formed. The conductive layers 510C may include a conductive material. For example, the conductive layers 510C may include a conductive material such as tungsten, molybdenum, or polysilicon.

Subsequently, the conductive layers 510C and the barrier layer 590A may be partially removed by etching the conductive layers 510C and the barrier layer 590A through the slit SL to expose the first material layers 510A. Through this, the barrier patterns 590 and the conductive layers 510C may remain in the openings OP. The barrier patterns 590 and the conductive layers 510C may be used as gate lines.

The barrier patterns 590 may increase the bonding strength of the conductive layers 510C. In addition, the barrier patterns 590 may prevent or reduce back tunneling of charges of the gate line to the second data storage patterns 570 and/or the first data storage layer 530. The barrier patterns 590 may increase a size of a work function required for back tunneling of the charges of the gate line. For example, compared to a case where the conductive layers 510C and the barrier patterns including TIN are bonded, when the conductive layers 510C and the barrier patterns 590 including at least one of TaN and WN are bonded, the size of the work function required for back tunneling of the charges of the conductive layers 510C may be increased. In this case, the energy required for back tunneling may increase and the charges may be prevented from being back tunneled.

A source select transistor, a memory cell, or a drain select transistor may be positioned in an area where the channel structure CH and the conductive layers 510C intersect. For example, at least one source select transistor, a plurality of memory cells, and at least one drain select transistor stacked along the channel structure CH may configure one memory string.

According to the prior art, a data storage layer may be formed as a single layer, and data storage layers of stacked memory cells may be connected to each other. When a gap between the conductive layers of the gate structure is reduced for improving the integration degree of the semiconductor device, charges may move between the stacked memory cells. Therefore, reliability of the memory cell may be reduced. The present invention addresses this issue and, thus, enables further improvements in the integration degree of semiconductor devices.

According to an embodiment of the present disclosure, a data storage layer included in the memory cells may be formed of a plurality of layers. For example, each of the memory cells may include the first data storage layer 530 and the second data storage pattern 570.

Here, a thickness of the first data storage layer 530 having a form in which the data storage layers of the stacked memory cells are connected to each other may be formed to be relatively thin. The first data storage layer 530 may be used as a seed layer for forming the second data storage patterns 570, and the second data storage patterns 570 may be selectively formed using the first data storage layer 530. Here, the second data storage patterns 570 may be formed at a level corresponding to the conductive layers 510C and may be spaced apart from each other in the vertical direction. Therefore, movement of the charge between the stacked memory cells may be reduced, and reliability of the memory cells may be increased.

Subsequently, a slit structure SLS may be formed in the slit SL. The slit structure SLS may include an insulating material, a conductive material, or a semiconductor material.

According to the manufacturing method described above, at least one of hydrogen and deuterium may be injected into the channel layer 550 through the openings OP. In this case, hydrogen or deuterium may be trapped in a trap site of a grain boundary existing in the channel layer 550. Therefore, layer quality of the channel layer 550 may be improved, and mobility of charges may be increased.

According to an embodiment of the present disclosure, the first data storage layer 530 may be used as a seed layer for forming the second data storage patterns 570, and the second data storage patterns 570 may be selectively formed. In this case, because the second data storage patterns 570 may be formed to be spaced apart from each other in the vertical direction, movement of the charges between the stacked memory cells may be reduced. Therefore, reliability of the memory cell may be increased.

The first blocking patterns 580A and the second blocking layers 580B may be formed between the first data storage layer 530 and the second data storage patterns 570 and the conductive layers 510C. In this case, a back tunneling phenomenon may be reduced by increasing a thickness of the blocking layers 580A and 580B through which the charges of the conductive layers 510C are required to tunnel. In addition, the second blocking layer 580B may include a material having a dielectric constant which is greater than a dielectric constant of the first blocking patterns 580A. In this case, energy required for back tunneling of the charges of the conductive layers 510C may increase, and the charges may be prevented from being back tunneled.

In addition, before forming the conductive layers 510C, the barrier layer 590A may be formed. The barrier layer 590A may increase the size of the work function required for back tunneling of the charges of the conductive layers 510C. In this case, the energy required for back tunneling of the charges of the conductive layers 510C may increase, and the charges may be prevented from being back tunneled.

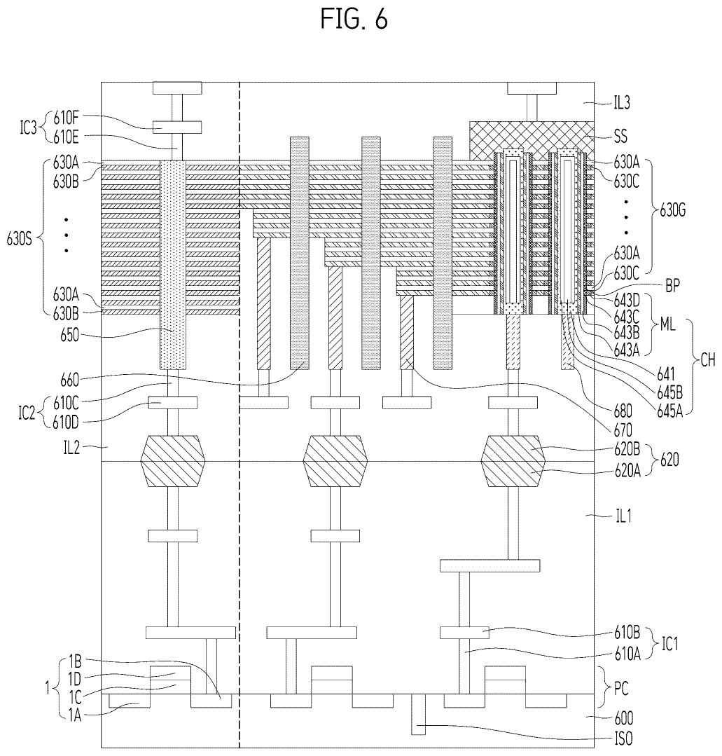

FIG. 6 is a drawing illustrating a semiconductor device according to an embodiment of the present disclosure. Hereinafter, a content that overlaps the content described above is omitted.

Referring to FIG. 6, the semiconductor device may include a substrate 600, a peripheral circuit PC, a source structure SS, a bonding structure 620, a stack 630S, a gate structure 630G, channel structures CH, a through plug 650, supports 660, a first contact via 670, second contact vias 680, an element isolation layer ISO, a first interconnection structure IC1, a second interconnection structure IC2, a third interconnection structure IC3, a first interlayer insulating layer IL1, a second interlayer insulating layer IL2, and a third interlayer insulating layer IL3.

The peripheral circuit PC may be positioned on the substrate 600. The peripheral circuit PC may include a transistor 1. The transistor 1 may include junctions 1A and 1B, a gate electrode 1D, and a gate insulating layer 1C. The element isolation layer ISO may be positioned in the substrate 600, and an active area of the transistor 1 may be defined by the element isolation layer ISO.

The first interconnection structure IC1 may be positioned on the peripheral circuit PC. The first interconnection structure IC1 may be positioned in the first interlayer insulating layer IL1. Here, the first interlayer insulating layer IL1 may be positioned on the substrate 600. The first interconnection structure IC1 may include first vias 610A and first lines 610B. The first interconnection structure IC1 may include a conductive material such as tungsten. The first interlayer insulating layer IL1 may include an insulating material such as oxide or nitride.

The bonding structure 620 may be positioned on the peripheral circuit PC. For example, the bonding structure 620 may be positioned on the first interconnection structure IC1. The bonding structure 620 may include first bonding pads 620A and second bonding pads 620B. The first bonding pads 620A may be positioned in the first interlayer insulating layer IL1. The second bonding pads 620A may be positioned on the first bonding pads 620A, and may be positioned in the second interlayer insulating layer IL2. Here, the second interlayer insulating layer IL2 may be positioned on the first interlayer insulating layer IL1. The bonding structure 620 may include a conductive material such as copper. The second interlayer insulating layer IL2 may include an insulating material such as oxide.

The second interconnection structure IC2 may be positioned on the bonding structure 620. The second interconnection structure IC2 may be positioned in the second interlayer insulating layer IL2. The second interconnection structure IC2 may include second vias 610C and second lines 610D. The second interconnection structure IC2 may be connected to the bonding structure 620. For example, at least one of the second vias 610C may be connected to the second bonding pad 620B. The second interconnection structure IC2 may include a conductive material such as tungsten.

The stack 630S may be positioned on the bonding structure 620. For example, the stack 630S may be positioned on the second interconnection structure IC2. The stack 630S may include insulating layers 630A and sacrificial layers 630B alternately stacked. The gate structure 630G may be positioned at a level corresponding to the stack 630S. The gate structure 630G may include insulating layers 630A and conductive layers 630C alternately stacked. The gate structure 630G may include an inverted step structure in which a lower surface of the conductive layers 630C is exposed.

For reference, an upper portion and a lower portion herein may be relative concepts for convenience of description. For example, the gate structure 630G may include a step structure in which an upper surface of the conductive layers 630C is exposed. The drawing may show a state in which the gate structure 630G is rotated. In other words, the drawing may show the gate structure 630G including an inverted step structure.

The through plug 650 may extend through the stack 630S and the second interlayer insulating layer IL2. The through plug 650 may be electrically connected to the peripheral circuit PC through the bonding structure 620. For example, the through plug 650 may be connected to the bonding structure 620 through the second interconnection structure IC2, and may be electrically connected to the peripheral circuit PC through the bonding structure 620. The through plug 650 may include a conductive material such as tungsten. However, the present disclosure is not limited thereto, and the through plug 650 may include an insulating material such as oxide as a support.

The channel structures CH may extend into the source structure SS through the gate structure 630G. Here, the source structure SS may be positioned on the gate structure 630G. Each of the channel structures CH may include at least one of a channel layer 641, a memory layer ML surrounding the channel layer 641, and a first insulating core 645A and a second insulating core 645B in the channel layer 641. Here, the channel layer 641 may be connected to the source structure SS. The memory layer ML may include at least one of a tunneling layer 643A, a first data storage layer 643B, second data storage patterns 643C, and blocking patterns 643D. The memory layer ML may further include buffer patterns BP.

For reference, the channel structures CH may correspond to the channel structures CH of FIGS. 1A and 1B. For example, the channel layer 641 may correspond to the channel layer 130 of FIGS. 1A and 1B, the memory layer ML may correspond to the memory layer ML of FIGS. 1A and 1B, and the first insulating core 645A and the second insulating core 645B may correspond to the first insulating core 190A and the second insulating core 190B of FIGS. 1A and 1B. Here, the tunneling layer 643A, the first data storage layer 643B, the second data storage patterns 643C, and the blocking patterns 643D of the memory layer ML may correspond to the tunneling layer 140, the first data storage layer 150, the second data storage patterns 160, and the blocking patterns 170 of FIGS. 1A and 1B. The buffer patterns BP may correspond to the buffer patterns 180 of FIGS. 1A and 1B.

However, the present disclosure is not limited thereto, and the channel structures CH may correspond to the channel structure CH of FIG. 2. For example, the channel layer 641 may correspond to the channel layer 230 of FIG. 2, the memory layer ML may correspond to the memory layer ML of FIG. 2, and the first insulating core 645A and the second insulating core 645B may correspond to the first insulating core 290A and the second insulating core 290B of FIG. 2. Here, the tunneling layer 643A, the first data storage layer 643B, the second data storage patterns 643C, and the blocking patterns 643D of the memory layer ML may correspond to the tunneling layer 240, the first data storage layer 250, the second data storage patterns 260, and the first blocking patterns 270 of FIG. 2. In addition, the channel structures CH may further include the second blocking layer BLL of FIG. 2.

The supports 660 may extend into the third interlayer insulating layer IL3 through the gate structure 630G. Here, the third interlayer insulating layer IL3 may be positioned on the gate structure 630G and/or the stack 630S. The supports 660 may include an insulating material such as oxide. The third interlayer insulating layer IL3 may include an insulating material such as oxide.

The first contact vias 670 may be connected to the conductive layers 630C of the gate structure 630G, respectively. For example, the first contact vias 670 may be extended through the second interlayer insulating layer IL2 to be respectively connected to the conductive layers 630C of which a lower surface is exposed through the inverted step structure of the gate structure 630G. The first contact vias 670 may include a conductive material such as tungsten.

The second contact vias 680 may be connected to the channel structures CH, respectively. For example, the second contact vias 680 may be extended through the second interlayer insulating layer IL2 to be respectively connected to the channel layer 240A of the channel structures CH. The second contact vias 680 may include a conductive material such as tungsten.

The third interconnection structure IC3 may be positioned in the third interlayer insulating layer IL3. The third interconnection structure IC3 may include third vias 610E and third lines 610F. At least one of the third vias 610E may be connected to the first contact via 670. At least one of the third vias 610E may be connected to the source structure SS. At least one of the third lines 610F may be connected to the third contact via 610E. The third interconnection structure IC3 may include a conductive material such as tungsten.

According to the structure described above, the semiconductor device may include the bonding structure 620. The bonding structure 620 may be positioned on the peripheral circuit PC and may be electrically connected to the peripheral circuit PC.

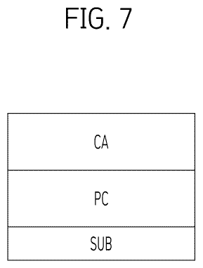

FIG. 7 is a configuration diagram of a semiconductor device according to an embodiment of the present disclosure. Hereinafter, a content that overlaps the content described above is omitted.

Referring to FIG. 7, the semiconductor device may include a substrate SUB, a peripheral circuit PC, and a memory cell array CA. Here, the peripheral circuit PC and the memory cell array CA may be formed in the same substrate.

The substrate SUB may include a semiconductor material. As an embodiment, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. As an embodiment, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method and may partially include a metal. The substrate SUB may have a single crystal, polycrystalline, or amorphous state. The substrate SUB may include an impurity of group II, group III, group IV, group V, or group VI. As an embodiment, the substrate SUB may include an n-well area doped with an n-type impurity and/or a p-well area doped with a p-type impurity.

The peripheral circuit PC may be positioned between the substrate SUB and the memory cell array CA. The peripheral circuit PC may include a row decoder, a column decoder, a page buffer, a logic circuit, a control circuit, a sense amplifier, an input/output circuit, and the like. As an embodiment, the peripheral circuit PC may include an NMOS transistor, a PMOS transistor, a register, a capacitor, and the like. The peripheral circuit PC may further include an interconnection structure. The interconnection structure may be used as a path for transmitting an operation voltage, and may include a contact plug, a line, and the like.

The memory cell array CA may include memory cells. As an embodiment, the memory cell array CA may include memory strings connected between a source line and a bit line, and each memory string may include stacked memory cells. As an embodiment, the memory cell array CA may include memory cells connected between a word line and a bit line. The memory cell array CA may further include an interconnection structure.

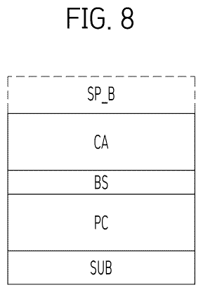

FIG. 8 is a configuration diagram of a semiconductor device according to an embodiment of the present disclosure. Hereinafter, a content that overlaps the content described above is omitted.

Referring to FIG. 8, the semiconductor device may include a substrate SUB, a peripheral circuit PC, a bonding structure BS, and a memory cell array CA. Here, the peripheral circuit PC and the memory cell array CA may be formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. As an embodiment, after manufacturing a first wafer including the memory cell array CA and a second wafer including the peripheral circuit PC, the first wafer and the second wafer may be electrically connected by the bonding structure BS. After bonding, the support base SP_B of the first wafer may be at least partially removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystal, a polycrystalline, or an amorphous state. The support base SP_B may include an impurity of group II, group III, group IV, group V, or group VI.

The bonding structure BS may be for connecting the cell array CA and the peripheral circuit PC. As an embodiment, the memory cell array CA and the peripheral circuit PC may be bonded by a wafer-on-wafer bonding method, a chip-on-wafer bonding method, a chip-on-chip bonding method, or the like. The bonding structure BS may include a bonding pad, a bonding interface, and the like. The bonding pad may include a metal and/or an alloy of copper, aluminum, or the like. The bonding interface may include a nonmetal-nonmetal interface, a metal-metal interface, or the like. The cell array CA and the peripheral circuit PC may be electrically connected by the bonding structure BS.

For reference, an interconnection structure included in the cell array CA and/or the peripheral circuit PC may be used as the bonding structure BS. As an embodiment, the interconnection structure included in the cell array CA and the interconnection structure included in the peripheral circuit PC may be directly bonded. In this case, a bit line, a source line, or the like may be used as the bonding structure without a separate bonding pad.

Other configurations may be equal to or similar to those described above with reference to FIG. 7.

Meanwhile, the semiconductor device may also have a structure in which the embodiments described above are combined with reference to FIG. 7 and FIG. 8, or may also have a partially modified structure. In the embodiment described with reference to FIG. 7 and FIG. 8, a position of the memory cell array CA and the peripheral circuit PC may be changed. In the embodiment described with reference to FIG. 8, at least one memory cell array CA and/or at least one peripheral circuit PC may be additionally bonded. As an embodiment, a portion of the peripheral circuit PC may be positioned in the memory cell array CA.

Although embodiments according to the technical concept of the present disclosure have been described with reference to the accompanying drawings, this is only for describing an embodiment according to the concepts of the present disclosure, and the present disclosure is not limited to the above-described embodiments. In the scope of the technical concepts of the present disclosure described in the claims, various forms of substitution, modification, and change of the embodiments will be possible by those skilled in the art to which the present disclosure belongs, and these also belong to the scope of the present disclosure. Furthermore, the embodiments may be combined to form additional embodiments.

What is claimed is:

1. A semiconductor device comprising:
a gate structure including alternately stacked insulating layers and conductive layers;
a slit structure extending through the gate structure;
a channel layer extending through the gate structure;
a first data storage layer surrounding the channel layer;
second data storage patterns respectively positioned between the conductive layers and the first data storage layer;
first blocking patterns respectively positioned between the conductive layers and the second data storage patterns; and
buffer patterns positioned between the insulating layers and the first data storage layer.

2. The semiconductor device of claim 1, wherein the first data storage layer has a thickness thinner than a thickness of the second data storage patterns.

3. The semiconductor device of claim 1, further comprising:
a second blocking layer including a first portion positioned between the conductive layers and the first blocking pattern, a second portion positioned between the insulating layers and the slit structure, and a third portion extending in a horizontal direction to connect the first portion and the second portion.

4. The semiconductor device of claim 3, wherein the second blocking layer includes a material having a dielectric constant which is greater than a dielectric constant of the first blocking patterns.

5. The semiconductor device of claim 4, wherein the first blocking patterns include silicon oxide, and the second blocking layer includes at least one of aluminum oxide, hafnium oxide, and zirconium oxide.

6. The semiconductor device of claim 5, wherein the first blocking patterns include SiO₂, and the second blocking layer includes at least one of Al₂O₃, HfO₂, and ZrO₂.

7. The semiconductor device of claim 1, further comprising:
barrier patterns surrounding the conductive layers.

8. The semiconductor device of claim 1, further comprising:
a first insulating core positioned in the channel layer; and
a second insulating core positioned in the first insulating core and having a stress different from a stress of the first insulating core.

9. The semiconductor device of claim 8, wherein the first insulating core includes nitride, and
the second insulating core includes oxide.

10. The semiconductor device of claim 1, wherein the channel layer includes at least one of hydrogen and deuterium.

11. The semiconductor device of claim 1, wherein the second data storage patterns include a material different from a material of the first data storage layer.

12. The semiconductor device of claim 11, wherein the first data storage layer includes silicon nitride, and the second data storage patterns include silicon carbonitride.

13. The semiconductor device of claim 12, wherein the first data storage layer includes Si₃N₄, and the second data storage patterns include SiCN.

14. The semiconductor device of claim 1, wherein the second data storage patterns include substantially the same material as the first data storage layer.

15. The semiconductor device of claim 14, wherein the first data storage layer and the second data storage patterns include silicon nitride.

16. The semiconductor device of claim 15, wherein the first data storage layer and the second data storage patterns include Si₃N₄.

17. The semiconductor device of claim 1,
wherein the buffer patterns include oxide.

18. A semiconductor device comprising:
a peripheral circuit;
a bonding structure positioned over the peripheral circuit;
a gate structure positioned over the bonding structure and including insulating layers and conductive layers alternately stacked;
a slit structure extending through the gate structure;
a source structure positioned on the gate structure; and
a channel structure extending into the source structure through the gate structure, and including a channel layer, a first data storage layer, second data storage patterns, first blocking patterns, and buffer patterns,
wherein the first data storage layer surrounds the channel layer, and the second data storage patterns are positioned between the conductive layers and the first data storage layer, respectively.

19. The semiconductor device of claim 18, wherein the first blocking patterns are respectively positioned between the conductive layers and the second data storage patterns, and
the buffer patterns are positioned between the insulating layers and the first data storage layer, respectively.

20. The semiconductor device of claim 18, wherein the first data storage layer has a thickness thinner than a thickness of the second data storage patterns.

21. The semiconductor device of claim 18, further comprising:
a second blocking layer including a first portion positioned between the conductive layers and the first blocking pattern, a second portion positioned between the insulating layers and the slit structure, and a third portion extending in a horizontal direction to connect the first portion and the second portion;
a first insulating core positioned in the channel layer; and
a second insulating core positioned in the first insulating core and having a stress different from a stress of the first insulating core.

22. The semiconductor device of claim 18, further comprising:
a through plug positioned over the bonding structure and electrically connected to the peripheral circuit;
a first interconnection structure connecting the peripheral circuit and the bonding structure; and
a second interconnection structure connecting the bonding structure and the through plug.
